(19) United States
(12) Patent Application Publication
(10) Pub. No.: US 2024/0192266 A1
(43) Pub. Date: Jun. 13, 2024

(54) Smart Connector Matrix - an electrical tool to design and test circuits without maneuvering components

(71) Applicant: Swaresh Borse, Allen, TX (US)

(72) Inventor: Swaresh Borse, Allen, TX (US)

(21) Appl. No.: 18/079,871

(22) Filed: Dec. 12, 2022

(51) Int. Cl. G01R 31/28

(52) U.S. Cl. CPC G01R 31/2848

(57) ABSTRACT

The present invention is an electrical device which can be used to design and test electronic circuits with close to null manual intervention. It consists of plurality of reed relays to establish electrical contact between two given points in a connector matrix which is also part of the tool. User can make and break these electrical connections by application software controlling the reed relays. This application is required to be installed on a computer which aids user interaction with the tool. A micro-controller, equipped with firmware, is used to manage interface between the reed relays and the application software. Additionally, an analog to digital converter chip is implemented to measure voltage between two points in a user circuit under test.

### CROSS REFERENCE TO RELATED APPLICATIONS

This application does not provide reference to any prior applications.

### BACKGROUND OF THE INVENTION

### 1. Field of Invention

The present invention relates to electrical and electronic tools wherein circuit designers and testers can create electrical contacts between electronic components without having to physically move wires or components.

### 2. Description of Related Art

Existing circuit simulators are mere mathematical formulations of physical electronic circuits with limited accuracy. Designing and testing circuits physically, takes lot of manual efforts—moving components around, connecting or disconnecting wires and many other maneuvers. In this process electronic components undergo a lot or wear and tear and there is a chance of damaging them.

Said invention addresses this concern by automating electrical contact creation between electronic components using software application. This gives users both circuit design agility and accuracy.

### SUMMARY OF THE INVENTION

The present invention comprises of a hardware apparatus, a software application to run said apparatus and a firmware to be installed in a micro-controller. The said micro-controller controls functioning of said apparatus. It is the heart of the said invention. It manages communication with the software application and enables creation and destruction of electrical contacts between user-provided electronic components. The said software application requires a host device such as a computer to house itself. This enable users to interact with said invention. Interaction between the said apparatus and the software application happens over a USB port of the said host device on which the software application is installed.

Other aspects of said invention include ability to create and save circuit designs, ability to reuse a previously saved project by importing relevant project files, customizable settings, ability to enable and disable different layers on a design panel, ability to generate reports, ability to measure voltage between any two electrical points in user-designed circuits, data logger functionality, troubleshooting functionality, apparatus reset functionality, error counter, log message counter, error notifications and recording logs of user activity.

### DETAILED DESCRIPTION OF INVENTION DRAWINGS

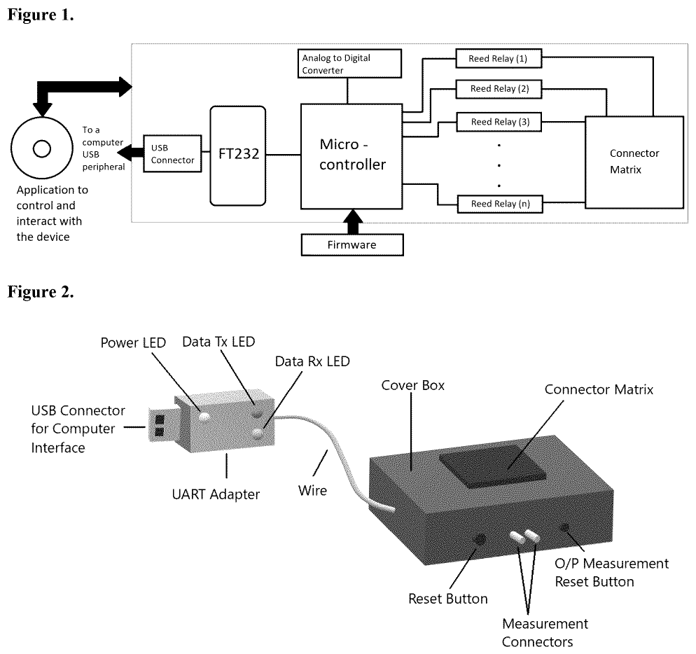

FIG. 1: shows a conceptual diagram of said invention. It consists of a micro-controller as a main block interfacing with other blocks such as an analog to digital converter, an array of reed relays and a FT232 chip for communication with software application over USB port of a computer device hosting said application software. A firmware is installed in the micro-controller to enable its functionality. Said array of reed relays interfaces with a connector matrix which hold user supplied electronic components.

FIG. 2: is a three dimensional pictorial representation of said hardware apparatus. The UART adapter consists of an FT232 chip which converts USB data signals to micro-controller readable bits and micro-controller transmitted bits to USB data signals. Said UART adapter has a USB connector to interface with a host computer running said software application. It has 3 LEDs—a power LED, data Tx LED and data Rx LED. Said power LED indicates power provided to the hardware apparatus. Said data Tx LED is indicative of data transmitted from said software application running on said host computer to said micro-controller. Said data Rx LED is indicative of data received by said software application running on said host computer from said micro-controller. A bulk of wire connects said UART adapter to cover box. Said cover box encloses said micro-controller, an analog to digital converter and an array of reed relays. Top exterior of said cover box has a connector matrix that enables users to mount electronic components. Side exterior of said cover box has a reset button which enables resetting of said hardware apparatus. Side exterior of said cover box has an output measurement reset button which enables resetting of voltage measurement. Side exterior of said cover box has two connectors denoted by “measurement connectors” in FIG. 2 from which a voltage between two points in a circuit can be measured.

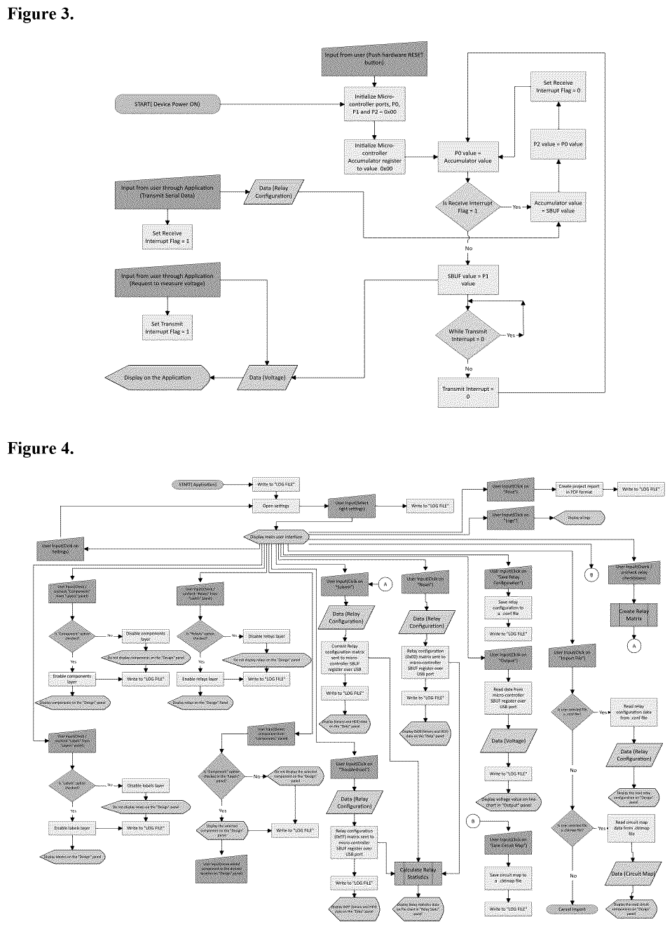

FIG. 3: is a flow chart illustrating algorithm of said firmware installed in said micro-controller. It demonstrates step by step functionality of said micro-controller. Upon power ON or if user presses said reset button (depicted in FIG. 2 paragraph of “Detailed description of invention drawings” section) when said hardware apparatus is already powered ON, said firmware resets micro-controller ports 0, 1, 2 and an accumulator register (a memory space inside said micro-controller) to hexadecimal value 0. Data in said accumulator register is moved to said port 0 of said micro-controller. The program then enters into a continuous loop where in it checks if data is being transmitted by said software application running on said host computer and also checks if said software application running on said host computer is requesting data to be transmitted from said micro-controller. Incoming data from said software application is stored in SBUF register (another memory space inside said micro-controller) of said micro-controller. Data from said SBUF register is moved to said accumulator register of said micro-controller. Any data in said port 0 is moved to said port 2 of said micro-controller. Data from said accumulator register is moved to said port 0 of said micro-controller. If data is requested from said software application, data from said port 1 is moved to said SBUF register of said micro-controller. Data from said SBUF register of said micro-controller is then transmitted to said software application running on said host computer.

FIG. 4: is a flow chart illustrating algorithm of said software application installed on said host computer. Settings window of said software application is opened. User is required to choose all the appropriate settings on the form. Upon closing the window a main user interface is displayed. Said main interface awaits user interactions.

When user checks or unchecks “components” option from a “Layers” panel, said main interface shows or hides, respectively, component images on a “Design” panel. When user checks or unchecks “labels” option from said “Layers” panel, said main interface shows or hides, respectively, labels on said “Design” panel. When user checks or unchecks “relays” option from said “Layers” panel, said main interface shows or hides, respectively, checkboxes representing reed relays on said “Design” panel.

A “Components” panel on said main user interface allows user to select an electronic component from a list. Selected components are drawn on said “Design” panel. User may move the added components in desired location on said “Design” panel.

Depending on the design, a user may check or uncheck any checkboxes on said “Design” panel. This information is converted into a binary matrix which is transmitted to said hardware apparatus when user clicks on “Submit” button.

When user clicks on “Troubleshoot” button, all said reed relays in said hardware apparatus are turned to ON state.

When user clicks on “Reset” button, all said reed relays in said hardware apparatus are turned to OFF state.

When user clicks on “Output” button, said hardware apparatus measures voltage across said measurement connectors (depicted in FIG. 2 paragraph of “Detailed description of invention drawings” section) and displays it in a line chart on an “Output” panel in said 100 main interface.

When user clicks on “Save Configuration” button, said binary matrix is saved in a file created with .conf extension.

When user clicks on “Save Circuit Map” button, said binary matrix is saved in a file created with .cktmap extension.

When user clicks “Import” button, said software application allows the user to pick a .conf file or .cktmap file which may have been previously saved. Contents of said files are then displayed on said “Design” panel.

When user clicks “Print” button, said application creates a PDF file displaying current project statistics.

All the above said processes are recorded in said log file. When user clicks on “Logs” button, all recorded logs are displayed.

### DETAILED DESCRIPTION OF INVENTION

The present invention can be broken down into three categories—a hardware apparatus, a software application and firmware.

A. HARDWARE: Said hardware consists of a connector matrix which a user can interact with to mount their electronic components. A micro-controller acts as a primary component that controls and manages all circuits.

One of the ports of said micro-controller is interfaced with an analog to digital converter (called ADC from here on). Said ADC enables present invention to measure voltage between two points in a user designed circuit.

Said micro-controller also interfaces with an FT232 chip on one of its ports to enable serial communication with said software application. A dedicated data transmitter pin on said FT232 chip interfaces with a dedicated data receiver pin on said micro-controller port. A dedicated data receiver pin on said FT232 chip interfaces with a dedicated data transmitter pin on said micro-controller port.

Other ports of said micro-controller are interfaced with multiple reed relays. Each pin of above said micro-controller ports is connected to one reed relay pin. This enables said micro-controller to control the state of said reed relays. By default all said reed relays are in OFF state. When a said micro-controller pin output is set to logical high (or binary ‘1’), the corresponding reed relay is turned ON. This creates an electrical contact between two points on said connector matrix. Said micro-controller has a reset functionality provided by a hard reset button (depicted in FIG. 2 paragraph of “Detailed description of invention drawings” section). All said micro-controller port pins, controlling said reed relays, are set to logical low state after user presses said reset button. This causes all reed relays to go in OFF state. Said hardware is powered by host computer running said software application over a USB port. Said USB port provides 5V which powers said FT232 chip, said micro-controller, said ADC and said reed relays.

B. SOFTWARE: Said application software enables user interaction with said hardware apparatus. It comprises of a user interface and added functionality to different aspects of said user interface. Said user interface consists of seven panels.

A “Design” panel is the main panel of said user interface. On this panel a user can add images of electronic components and change state of said reed relays. Said design panel has multiple layers—components layer, relays layer and labels layer.

A “Layers” panel provides functionality to enable or disable above said layers of said “Design” panel.

A “Components” panel enables user to pick from any components and lay it on said “Design” panel.

A “Data” panel is used to view relay statuses in form of a matrix represented by binary and decimal format.

A “Relay Stats” panel represents number of relays in ON and OFF state in form of a pie chart.

An “Output” panel represents voltage measured from said measurement connectors (depicted in FIG. 2 paragraph of “Detailed description of invention drawings” section) in form of a line chart.

A “Logs” panel records all activity associated with said hardware and software. It also records number of errors encountered and total number of logs reported.

A menu bar includes all functions described in FIG. 4 paragraph of “Detailed description of invention drawings” section.

This functionality to said user interface is added with approximately 6500 lines of C#programming language code. Each user activity is encoded as a separate C #function definition. All said functional definitions interact with each other to achieve the desired results for user.

C. FIRMWARE: Said firmware provides functionality to said hardware apparatus. It is embedded in said micro-controller to manage various aspects described in point “A. HARDWARE” of this section. Said firmware is programmed in Embedded C and contains approximately 50 instructions. Said instructions include setting and/or resetting different registers and ports on said micro-controller, checking specific flag bits on said micro-controller, setting baud rate for said micro-controller communication with said USB port of said host computer running said software application.

The invention claimed is:

1. An electrical tool, capable of communicating with a computer, comprising:
a micro-controller;
a software application;
a USB to UART and UART to USB converter;
a plurality of reed relays interfacing with said micro-controller;
a plurality of connectors interfacing with said reed relays forming a connector matrix to hold electronic components by their electrical pins; and
an analog to digital converter interfacing with said micro-controller.

2. An electrical tool as in claim 1, wherein said micro-controller is a plurality of micro-controllers interacting with each other.

3. A method of designing and testing circuits physically, comprising the steps of:
communicating with said software application to receive user commands;
making and/or breaking several electrical contacts between user defined circuit points with use of said software application; and
measuring voltage between two physical points in user designed circuit and displaying said voltage on user interface of said software application.
